(19) United States
(12) Patent Application Publication
(10) Pub. No.: US 2024/0224430 A1
(43) Pub. Date: Jul. 4, 2024

(54) SYSTEMS AND METHODS FOR MANUFACTURING PRINTED CIRCUIT BOARDS

(71) Applicant: Prashant Patil, Cambridge, MA (US)

(72) Inventor: Prashant Patil, Cambridge, MA (US)

(21) Appl. No.: 18/402,903

(22) Filed: Jan. 3, 2024

Related U.S. Application Data
(60) Provisional application No. 63/436,971, filed on Jan. 4, 2023.

(51) Int. Cl. H05K 3/22; C25D 5/00; C25D 5/48; C25F 3/16

(52) U.S. Cl. CPC H05K 3/225; C25D 5/48; C25D 5/611; C25D 5/67; C25F 3/16

(57) ABSTRACT

Systems and methods for overcoming technical problems associated with machining and manufacturing printed circuit boards. In some embodiments, the systems and methods include a process to remove or reduce defects in initially created printed circuit board (PCB) traces. For example, a method can include a process to remove or reduce burrs of laser micromachined PCB traces (which can be electrically isolated from each other). In some cases, a material is deposited over the PCB traces, and the depositing results in a conducting layer that electrically connects all or most of the PCB traces and provides an electrical connection for removing or reducing the defects in the PCB traces.

### CROSS-REFERENCE TO RELATED APPLICATION

This application claims the benefit of priority from U.S. Provisional Patent Application No. 63/436,971, titled “METHOD FOR MANUFACTURING ULTRA-HIGH-DENSITY MINIATURIZED PRINTED CIRCUIT BOARDS”, filed on Jan. 4, 2023, which is also incorporated herein by reference in its entirety.

### TECHNICAL FIELD

The present disclosure relates to the technical field of machining and manufacturing of printed circuit boards (PCBs).

### BACKGROUND

Printed circuit boards or PCBs are often used in electronic products. A trend in the miniaturization of electronic devices has led to miniaturizing printed circuit boards, reducing trace width, and spacing. Moreover, the past decade has witnessed a considerable slowing of Moore's law, leading to the development of alternate ways to fabricate chips such as heterogeneous integration of chiplets and advanced packaging, further creating a demand for reducing a printed circuit board (PCB) trace width and spacing.

Conventional PCB manufacturing processes may have reached the limit of reducing PCB trace width and spacing. The state-of-the-art PCB manufacturing processes can use photolithography and wet chemical etching to fabricate PCB traces. The wet chemical etching process is an isotropic etching process, and it etches material at the same rate in both vertical and lateral directions typically, thereby limiting the etched trench depth-to-width aspect ratio to less than 1:2 ratio. Often, etching 18 μm thick copper to create PCB traces results in a 50 μm or more gap between the traces. Moreover, the PCB traces have a trapezoidal cross-section, resulting in signal distortion in high-speed RF applications. Also, many of the known PCB manufacturing processes can be polluting due to their use of various toxic chemicals, such as resists, developers, and etchants.

Although laser micromachining can be used to fabricate PCBs and may provide a technical solution to the previously mentioned issues, its application has been limited to fabricating PCBs with large trace width and spacing due to the burrs produced during laser micromachining. These burrs typically range from several microns to approximately 50 μm in size. When the trace width and spacing are much larger than the burrs, the burrs do not cause any shorts between the traces. Moreover, as the burrs can be much smaller than the PCB traces, the burrs can be removed by wet etching without completely etching away the traces. However, as the trace spacing is reduced below approximately 50 μm and the burr size becomes comparable to the trace spacing, the burrs cause shorts between the traces. Moreover, when building multi-layer PCB by laminating multiple PCB trace layers, burrs can puncture through the insulating layer used to separate conducting trace layers and cause shorts between them. The sharp burrs also result in an electric discharge, resulting in a dielectric breakdown of the insulating layer used between the conducting layer or traces.

Removing burrs is difficult as the trace width and spacing are reduced, and the burr size becomes comparable to the PCB trace width and spacing. Using wet etching to remove burrs also etches away the PCB traces, and using physical polishing destroys the fragile PCB traces. Thus, the burrs produced during laser micromachining limit smaller PCB trace width and spacing that can be produced using laser micromachining.

Electro-deburring, Electro-polishing, and Plasma Electrolytic Polishing (PeP) can be used to remove burrs from a microstructure without etching away the microstructure. However, these processes may require making an electrical connection to the microstructure (such as PCB trace) that needs to be deburred. And, in a PCB, there are many, typically hundreds, of electrically isolated traces (or island structures). Making electrical connections to hundreds of highly dense PCB traces using an array of probes is not practical.

If the known electro-deburring, electro-polishing, or PeP process is used for deburring PCBs, the burrs are removed only from the trace where an electrical connection is made (e.g., see FIG. 1D), while other electrically isolated traces would remain burred (e.g., see FIGS. 1D to 1F). Thus, in a practical sense, the known electro-deburring, electro-polishing, and PeP processes cannot be used to remove burrs from laser-micromachined PCB traces with smaller dimensions.

### SUMMARY OF THE INVENTION

Described herein are systems and methods for overcoming technical problems associated with machining and manufacturing printed circuit boards or PCBs. In some embodiments, the systems and methods include a process to remove or reduce defects in initially created printed circuit board PCB traces. For example, a method can include a process to remove or reduce burrs of laser micromachined PCB traces (in which the traces can be electrically isolated from each other). In some embodiments, a material is deposited over initially created PCB traces, and the depositing results in a conducting layer that electrically connects all or most of the PCB traces and provides an electrical connection for removing or reducing defects in the PCB traces (such as reducing or eliminating burrs formed in laser micromachining). With respect to some embodiments, disclosed herein is an electro isle deburring (EID) process to deburr laser micromachined PCB traces, e.g., deburring traces that are electrically isolated from each other.

Also, with respect to some embodiments, disclosed herein are processes for improving the machining and manufacturing of multi-layer PCBs. A group of layers of a multi-layer PCB can each be put through a round of depositing of material over the PCB traces and the removal or reduction of defects in the layer from the deposited material providing a conducting layer electrically connecting all or most of the PCB traces and an electrical connection for removing or reducing the defects in the PCB traces (such as reducing or eliminating burrs formed in laser micromachining of layers of a multi-layer PCB).

In some embodiments, an example method includes depositing a conducting layer over traces formed on a PCB, the traces being electrically isolated from each other and the conducting layer electrically connecting at least some of the traces after the conducting layer is deposited. The example method can also include applying an electrical current to the conducting layer to reduce or eliminate defects on or in the traces. In some examples, the PCB is micromachined using laser micromachining. In some examples, at least some of the defects are formed from laser micromachining. And, in some cases, at least some of the defects include burrs. Thus, in some embodiments, an example method includes depositing a conducting layer over traces formed on a laser micromachined PCB, the traces being electrically isolated from each other and the conducting layer electrically connecting at least some of the traces after the conducting layer is deposited. Such a method can also include applying an electrical current to the conducting layer to reduce or eliminate burrs on the traces.

In some cases, the example method can include the creation of the traces. For example, the method can include laser micromachining of the PCB traces. In some cases, at least some of the traces are not connected by a deposited conducting layer. In some of such cases, at least some of the traces are connected electrically in another known or foreseeable way to a person having ordinary skill in the art. In such examples without the depositing of the conducting layer, the defects or burrs may or may not be reduced or eliminated in the method.

In some embodiments, one or more steps of the example method can be repeated to produce a multi-layer PCB. In some cases, for instance, the example method includes, for each layer of a plurality of layers of a multi-layer PCB, repeating laser micromachining of PCB traces. In some embodiments, for each layer of a plurality of layers of the multi-layer PCB, the example method includes repeating depositing a conducting layer over traces formed on a laser micromachined PCB. Also, in some cases, for each layer of a plurality of layers of the multi-layer PCB, the example method includes applying an electrical current to the conducting layer to reduce or eliminate burrs on the traces. In some cases, the example method includes the repeating of an EID process (such as a process including the previously mentioned sub-processes of depositing a conducting layer over traces and applying an electrical current to the conducting layer to reduce or eliminate burrs on the traces). And, in some cases, the example method includes forming vias between the plurality of layers of the multi-layer PCB after the repeating of the laser micromachining of PCB traces and the EID process.

For instance, in some embodiments, an example method includes using an EID process to reduce or eliminate burrs occurring on printed PCB traces, in which the PCB traces are electrically isolated from each other before performing the EID process. The EID process can include, as a first sub-process, depositing a conducting layer over the PCB traces, resulting in the conducting layer electrically connecting at least some of the PCB traces. And, the EID process can include, as a second sub-process, applying an electrical current or voltage to the conducting layer to reduce or eliminate the burrs.

In some cases, the reduction or elimination of the burrs depends upon a voltage and an electrolyte used by applying the electrical current to the conducting layer. And, in some examples, using the previously mentioned second sub-process, reduction or elimination of the burrs by the second sub-process depends upon a voltage and an electrolyte used for the second sub-process. In some embodiments, the voltage used for the second sub-process, or a similar process, is determined according to the composition of the traces, the conducting layer, or a combination thereof. In some embodiments, the second sub-process, or a similar process, includes electro-polishing the traces. In some embodiments, the second sub-process, or a similar process, includes electro-deburring the traces. In some embodiments, the second sub-process, or a similar process, includes plasma electrolytic polishing the traces.

In some embodiments, the first sub-process includes using PVD, CVD, ALD, or any combination thereof. In some embodiments, the first sub-process includes using electroless copper. In some embodiments, the first sub-process includes using liquid metal ink. In some embodiments, the first sub-process includes using electroplating to increase the thickness of the conducting layer.

In some embodiments, the example method includes, after the EID process, or a similar process, removing the conducting layer using chemical etching. In some embodiments, the conducting layer includes a thin film conducting layer. In some embodiments, the example method includes forming the PCB traces over an insulating substrate. In some embodiments, the depositing of the conducting layer over the PCB traces provides for the conducting layer to electrically connect all the PCB traces.

In summary, the systems, and methods (or techniques) disclosed herein can provide specific technical solutions to at least overcome the technical problems mentioned herein as well as other technical problems not described herein but recognized by those skilled in the art.

These and other important aspects of the invention are described more fully in the detailed description below. The invention is not limited to the methods and systems described herein. Other embodiments can be used and changes to the described embodiments can be made without departing from the scope of the claims that follow the detailed description. Within the scope of this application, it should be understood that the various aspects, embodiments, examples, and alternatives set out herein, and individual features thereof may be taken independently or in any possible and compatible combination. Where features are described with reference to a single aspect or embodiment, it should be understood that such features are applicable to all aspects and embodiments unless otherwise stated or where such features are incompatible.

### BRIEF DESCRIPTION OF THE DRAWINGS

The present disclosure will be understood more fully from the detailed description given below and from the accompanying drawings of various example embodiments of the disclosure.

FIGS. 1A to 1F illustrate separate and known process steps for an electro-deburring process and are provided in order of operation sequence starting with the step in FIG. 1A and ending with the step in FIG. 1F.

FIGS. 2A to 2K illustrate separate process steps for an electro isle deburring process and are provided in order of operation sequence starting with the step in FIG. 2A and ending with the step in FIG. 2K, in accordance with some embodiments of the present disclosure.

FIGS. 3A to 3O illustrate separate process steps for manufacturing PCBs by laminating conducting and dielectric laminates and using laser micromachining followed by electro isle deburring to define PCB traces and are provided in order of operation starting with the step in FIG. 3A and ending with the step in FIG. 3O, in accordance with some embodiments of the present disclosure.

FIG. 4 shows a multi-layer PCB with an air gap between the traces for various applications such as high-speed applications, in accordance with some embodiments of the present disclosure.

FIG. 5 shows PCB layers created on both sides of the PCB core and with the air gaps filled with dielectric material, in accordance with some embodiments of the present disclosure.

FIGS. 6A to 6M illustrate separate process steps for manufacturing PCBs by depositing conducting and dielectric layer layers and using laser micromachining followed by electro isle deburring to define PCB traces on conducting layer and are provided in order of operation starting with the step in FIG. 6A and ending with the step in FIG. 6M, in accordance with some embodiments of the present disclosure.

FIG. 7 shows PCB layers created on both sides of the core, in accordance with some embodiments of the present disclosure.

FIGS. 8A to 8F illustrate separate process steps for fabricating double-sided PCB and are provided in order of operation starting with the step in FIG. 8A and ending with the step in FIG. 8F, in accordance with some embodiments of the present disclosure.

FIGS. 9A to 9G illustrate separate process steps for fabricating multi-layer PCBs by laminating double-sided PCB laminates and are provided in order of operation starting with the step in FIG. 9A and ending with the step in FIG. 9G, in accordance with some embodiments of the present disclosure.

### DETAILED DESCRIPTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, embodiments of the present invention provide improved systems, apparatus, and methods for manufacturing printed circuit boards (PCBs) and PCBs.

Details of example embodiments of the invention are described in the following detailed description with reference to the drawings. Although the detailed description provides reference to example embodiments, it is to be understood that the invention disclosed herein is not limited to such example embodiments. But to the contrary, the invention disclosed herein includes numerous alternatives, modifications, and equivalents as will become apparent from consideration of the following detailed description and other parts of this disclosure.

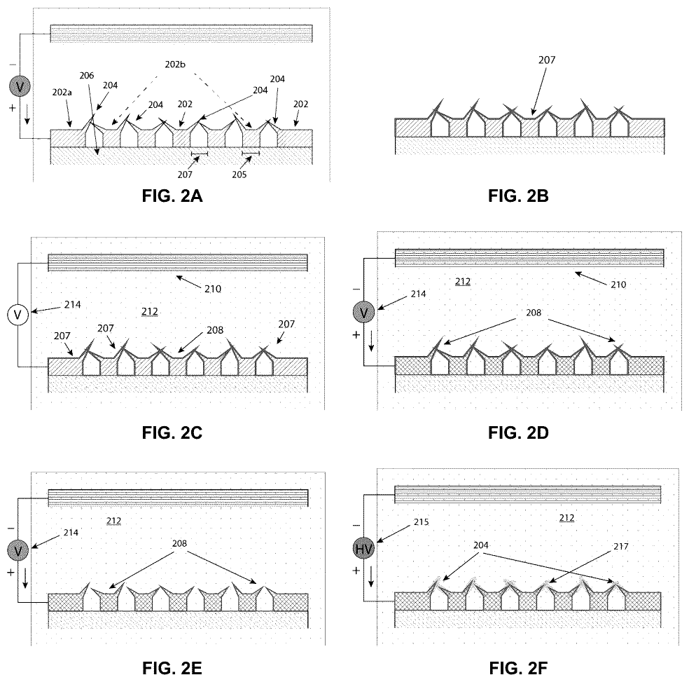

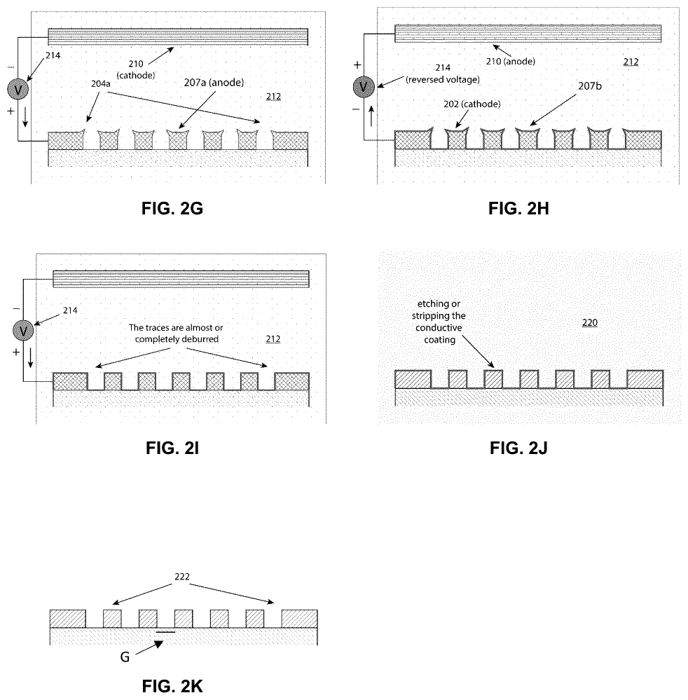

Described herein are systems and methods for overcoming technical problems associated with machining and manufacturing circuit boards (e.g., see the methods of processing PCBs shown in FIGS. 2A to 2K, FIGS. 3A to 3O, FIG. 4, FIG. 5, FIGS. 6A to 6M, FIG. 7, FIGS. 8A to 8F, and FIGS. 9A to 9G). In some embodiments, the systems and methods include a process to remove or reduce defects in initially created PCB traces. For example, a method can include a process to remove or reduce burrs of laser micromachined PCB traces (in which the traces can be electrically isolated from each other). In some embodiments, a material is deposited over initially created PCB traces, and the depositing results in a conducting layer that electrically connects all or most of the PCB traces and provides an electrical connection for removing or reducing defects in the PCB traces (such as reducing or eliminating burrs formed by laser micromachining). With respect to some embodiments, disclosed herein is an EID process to deburr laser micromachined PCB traces, e.g., deburring traces that are electrically isolated from each other. E.g., see FIGS. 2A to 2K.

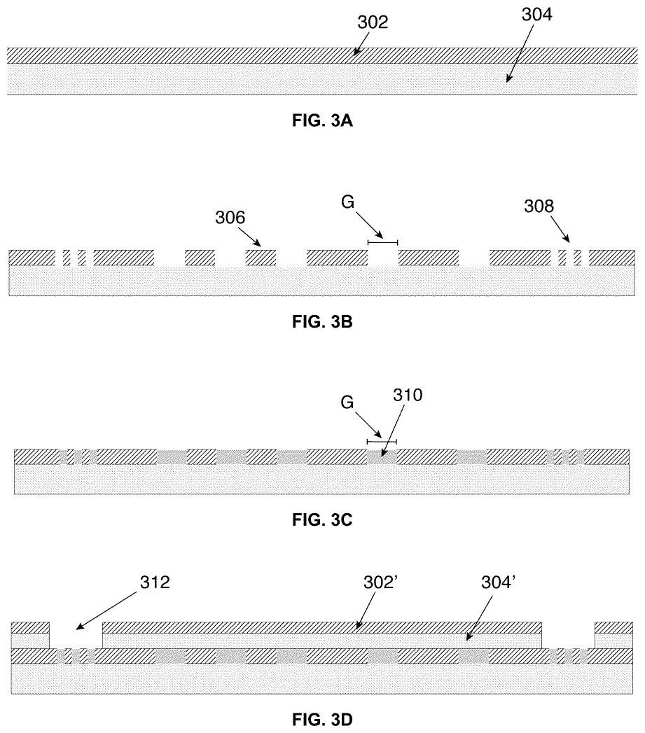

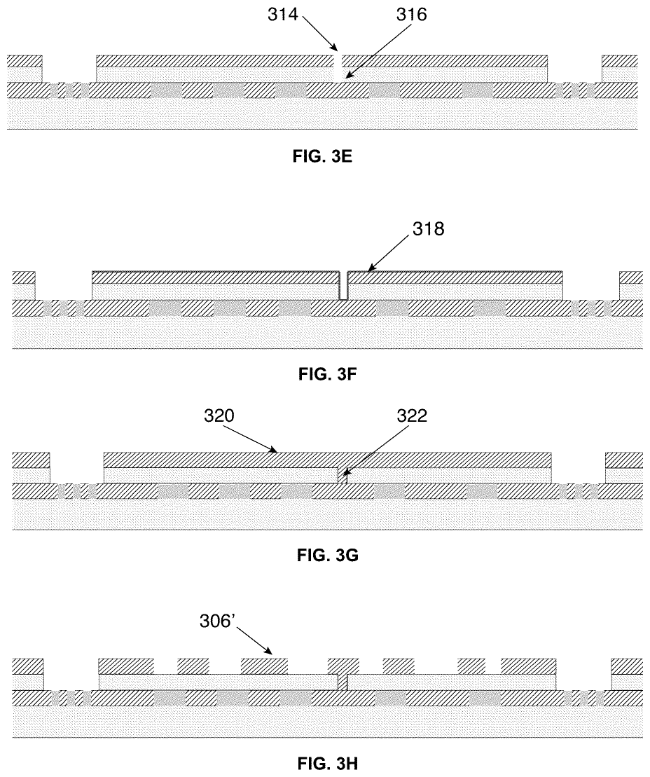

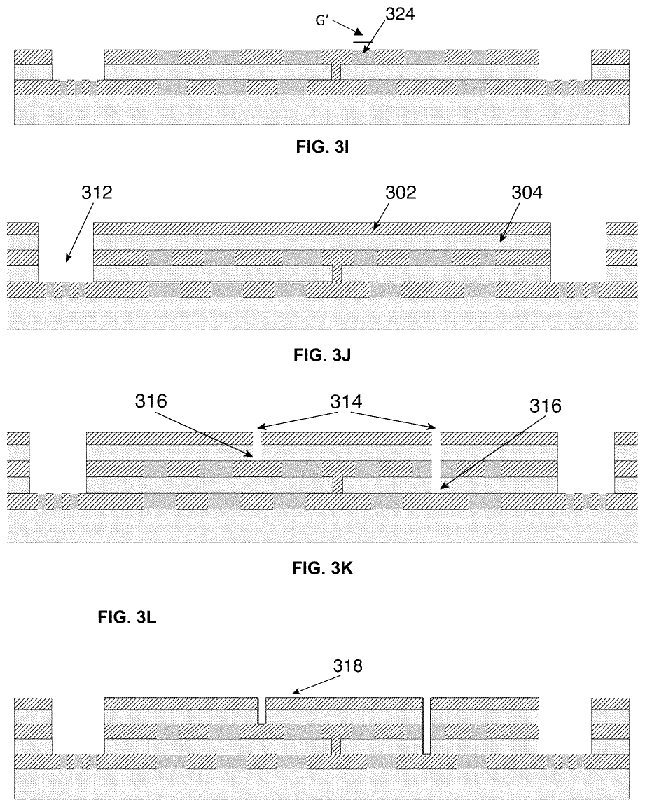

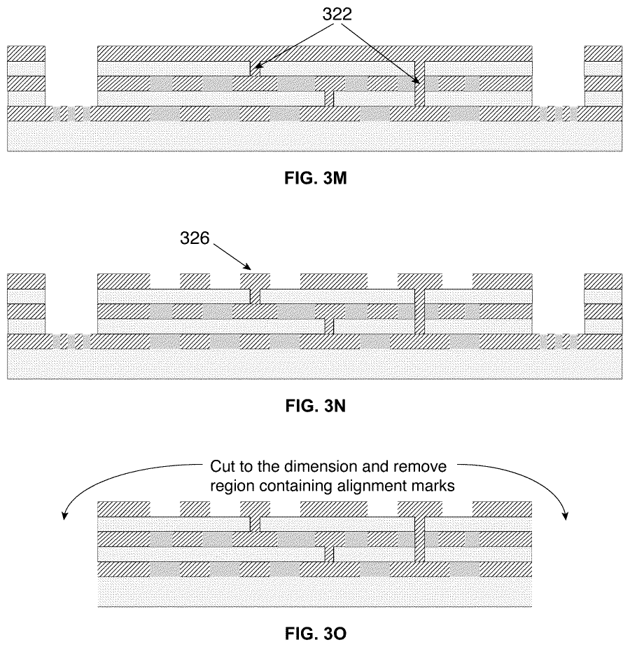

Also, with respect to some embodiments, disclosed herein are processes for improving the machining and manufacturing of multi-layer PCBs. E.g., see FIGS. 3A to 3O. A group of layers of a multi-layer PCB can each be put through a round of depositing of material over the PCB traces and the removal or reduction of defects in the layer from the deposited material providing a conducting layer electrically connecting all or most of the PCB traces and an electrical connection for removing or reducing the defects in the PCB traces (such as reducing or eliminating burrs formed in laser micromachining of layers of a multi-layer PCB).

In some embodiments, a method and others described herein, a thin-film conducting is deposited over the laser micromachined PCB traces. E.g., see FIG. 2B. The depositing results in a conducting layer that electrically connects all or most of the isolated PCB traces of the laser micromachined PCB traces and provides an electrical connection (or flow of current) for electro-deburring. In some cases, the depositing results in a conducting layer that electrically connects all or most of the isolated PCB traces of the laser micromachined PCB traces and provides an electrical connection (or flow of current) for electro-deburring all or most of the produced burrs. E.g., see FIG. 2D.

For the purposes of this disclosure, electro isle deburring is the process of deburring isolated structures (such as structures that are not electronically connected). Alternatively, or in addition to electro isle deburring, electro-deburring, electro-polishing, or PeP can be used to deburr electrically connected or monolithic conducting structures (or continuous structures). However, in a printed circuit board, there are many electrically isolated island traces (e.g., the PCB traces can be electrically conducting island structures over an insulating substrate), and electro-deburring, electro-polishing, or plasma electrolytic polishing cannot be used to deburr such PCB traces when the traces are very small. On the contrary, electro isle deburring can be used to deburr very small and electrically isolated island traces.

With respect to some examples, disclosed herein is a novel technique referred to herein as electro isle deburring, which overcomes the previously mentioned limitations of electro-deburring, electro-polishing, and plasma electrolytic polishing and enables deburring island PCB traces. Also, with respect to some examples, described herein is an electrical deburring process to deburr plurality of electrically isolated island PCB traces (e.g., wires) formed over an insulating substrate. In such a process, a thin film conducting layer is deposited over an island (or isle) trace to electrically bridge most or all traces, and the conducting layer electrically connecting the traces is used as an electrode of an electrochemical cell. Electrical connections are made to the conducting layer, and a suitable cell voltage waveform is applied to deburr PCB traces. The deburring is performed using various mechanisms at the electrode such as electro-polishing, electro-deburring, and plasma electrolytic polishing, while periodically regenerating the conducting film by reversing voltage and performing electroplating. E.g., see FIG. 2H. Subsequently, the conducting layer is etched away to electrically isolate PCB traces.

In some examples, electro-deburring, electro-polishing, and plasma electrolytic polishing contain an anode (usually the part that is deburred), a cathode, and an electrolyte. The difference is in the mechanism at the electrode that is used to remove burrs, and the mechanisms depend upon the voltage and electrolyte used.

For the purposes of this disclosure, electro-polishing is an electrochemical and reverse electroplating process used for surface smoothening. In the process, the metal part that needs surface smoothing is used as an anode of an electrochemical cell. A suitable cell voltage is applied, which creates a high-resistance viscous layer, or polishing film, around the anode. The polishing layer creates a high resistance path between the anode and the electrolyte; however, the “peaks” or “hills” present on the anode surface protrude through the polishing film, resulting in a localized low resistance path. The low resistance at peaks results in high current density and causes metal to dissolve faster at peak as compared to depressions or flat areas, thereby smoothing the surface. The electro-polishing process can be used to remove burrs if the burrs are small and comparable to the surface roughness of the part.

For the purposes of this disclosure, electro-deburring is an electrochemical and reverse electroplating process to remove burrs from a metal part. In the process, the metal part that needs deburring is used as an anode of an electrochemical cell. A suitable cell voltage (typically higher than the electro-polishing voltage) is applied, resulting in current density proportional to the electric field. The electric field is concentrated at the burrs due to their sharp peak structure, resulting in higher current density. The high current density at peaks causes the metal to dissolve faster at peak as compared to the flat area, thereby removing burrs. The electro-deburring process is used when burrs are much larger than the surface roughness of the part. In both electro-polishing and electro-deburring, the high current density at the burrs (or peaks) causes the metal to dissolve faster at peak as compared to depression or flat area, thereby resulting in the removal of burrs. However, the mechanics that result in high current density at burr (or peak) are different for electro-polishing and electro-deburring. In electro-polishing, the current density is higher at the burrs (peaks or hills) because they protrude through the high resistance polishing film and have a thinner film over them, resulting in low resistance and high current density. In electro-deburring, the high current density at burrs is due to the concentration of the high electric field at the burrs. The sharp structures of burrs result in the concentration of the electric field.

For the purposes of this disclosure, plasma electrolytic polishing or PeP is a process used for surface smoothing. In the process, the metal part that is surface smoothed is used as an anode of an electrochemical cell. A high cell voltage is used to create electric discharge and plasma at the sharp burrs. The discharge or plasma is formed at the burrs due to the evaporation of the electrolyte and ionization of vapors. The generated plasma causes plasma etching of burrs, thereby removing burrs.

In some embodiments, in the EID process, a thin-film layer of conducting coating is deposited over the laser-micromachined PCB. Typically, the thin film conducting layer is substantially thinner than the PCB traces so that the conducting layer is etched away without significant etching of the PCB traces. Typically, the conducting layer thickness is 1/10-1000th of the thickness of the PCB traces (depending on PCB trace thickness). For example, a 100 nm thick conducting layer can be used for 25 micrometer thick PCB traces. The thickness of the conducting layer should strike a balance, being substantial enough to ensure an effective conducting path for the deburring current, but not excessively thick to the extent that subsequent etching in the process significantly alters the dimensions of the PCB traces. The thickness of the conducting layer depends upon multiple parameters as described below.

For a given PCB board design, the number of burrs produced during laser-micromachining PCB traces depends upon the board design, trace thickness, and laser micromachining parameters used. The number of burrs present on the PCB traces determines the deburring current required to completely remove these burrs in the electro isle deburring process.

The deburring current depends upon the effective electrical conductance between the burr and the electrode contact on the conducting layer and has two components: 1) conductance through the deposited thin film conducting layer, and 2) conductance through the PCB traces.

The conductance through PCB traces is determined by the board design (trace layout, trace thickness, etc.) and determines the thickness of the conducting layer to achieve sufficient deburring current. In summary, the number of burrs present on traces determine the deburring current and the deburring current determines along with the PCB trace layout determine the thickness of the thin film conducting layer. List below summarizes the relationship between thickness t and other parameters: 1) t α number of burrs, 2)t α 1/deburring time, 3)t α trace spacing, 4) t α 1/trace width.

Next, an anodic electrical connection is made to the thin film conducting layer (e.g., see FIG. 2D), and burrs are removed using electro-deburring, electro-polishing (e.g., for small burrs), or plasma electrolytic polishing. Since the conducting layer electrically connects all or most PCB traces, the burrs can be removed from most or all PCB traces (e.g., see FIG. 2E).

In some embodiments, for certain conducting layer material, the conducting coating can get partially removed due to the electrolytic deburring (e.g., electro-deburring, electro-polishing, or plasma electrolytic polishing). For such materials, the thickness of the conducting layer can be increased by reversing the electrochemical cell voltage and performing electroplating over the conducting film (e.g., see FIG. 2G). In the electroplating cycle, cell parameters are set to maximize the uniform electroplating, while in the deburring cycles, these parameters are set to maximize selective electrochemical etching of burrs. After the deburring process, the thin-film conducting coating is etched away using flash wet-chemical etching, plasma etching, or similar methods to electrically isolate PCB traces (e.g., see FIG. 2I). Since the conducting coating is much thinner than the thickness of the PCB traces, it is removed without etching away the PCB traces.

In some embodiments, one or more of the previously mentioned techniques are used to fabricate multi-layer PCBs (such as multi-layer ultra-high-density PCBs). In such processes, PCB traces are formed on a metal-insulator laminate substrate using laser micromachining followed by disclosed electro isle deburring process (e.g., see FIG. 3B). Subsequently, a second metal-insulator layer is laminated over the substrate layer (e.g., see FIG. 3D). Afterward, laser-vias are formed (e.g., via drilling) in the second metal-insulator layer (e.g., see FIG. 3E) and electroless plating followed by electroplating is used for via-fill and electrically connect the two laminate layers (e.g., see FIG. 3F). Subsequently, laser micromachining followed by electro isle deburring is used to create PCB traces on the second metal laminate layer (e.g., see FIG. 3G). The process steps, shown in FIGS. 3D to 3G, can be repeated to create a multi-layer stack-up until a selected PCB layer count occurs. FIG. 3H shows the schematic diagram of the finished multi-layer PCB.

With some embodiments, the disclosed PCB manufacturing process has the following advantages over known PCB manufacturing processes: 1) ultra-high-density PCB wiring, 2) vertical wall of PCB traces resulting in better signal integrity, 3) tight control over trace impedance for high data propagation application, 4) making PCB with traces using a wide range of materials such as metals, alloys, conducting polymers, etc., 5) PCB with air-gap between traces for high data propagation application, and 6) High-aspect ratio PCB traces for high density and high-current application.

In some embodiments, ultra-high-density and miniaturized PCBs can be used as a substrate for ultra-high-density wiring in advanced semiconductor packaging, in mobile and wearable devices where space is limited, in applications having a tight control on impedance, such as 5G or 6G applications, and high-density flexible cables. In addition, the disclosed electro isle deburring process can also be used to deburr other island structures found in other applications, such as micro-electromechanical systems (MEMS), microfluidics, etc.

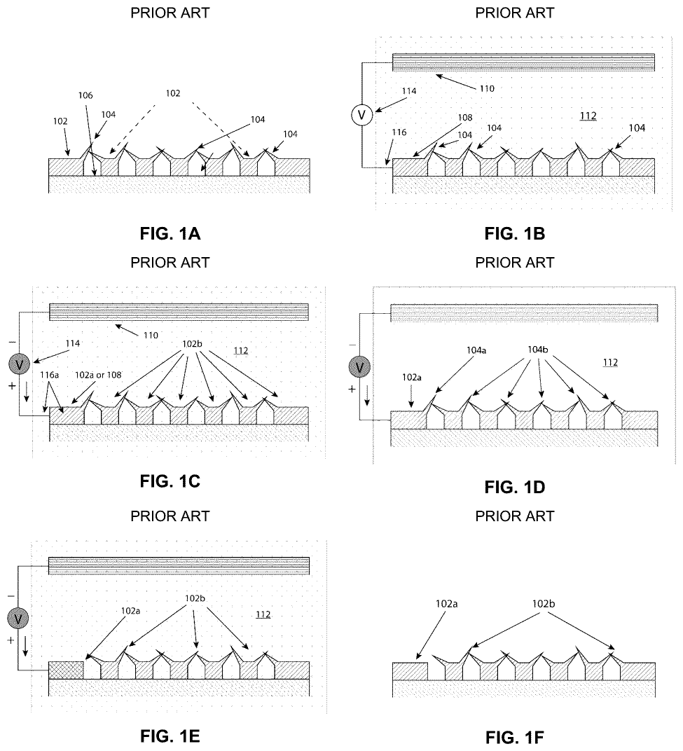

Specifically, FIGS. 1A to 1F illustrate separate and known process steps for an electro-deburring process and are provided in order of operation starting with the step in FIG. 1A and ending with the step in FIG. 1F. Although the steps of FIGS. 1A to 1F are known prior art processes and many of the technical problems associated with the known prior art processes have been overcome by solutions provided herein, one or more of the steps shown in FIGS. 1A to 1F can be combined with novel aspects of some embodiments of the present disclosure and, in some cases, when combined with some aspects of some embodiments of the present disclosure, the combination is novel. FIG. 1A illustrates PCB with laser-micromachined traces 102 showing burrs 104 present at the traces due to the laser micromachining process. As shown, the laser-micromachined traces 102 are on an insulating substrate 106 which is a part of the PCB. FIG. 1B illustrates a setup of a known electro-deburring process. It includes laser-micromachined PCBs including an anode 108 and a cathode 110. Also, included is electrolyte 112, a power supply 114, and electrical connections 116. FIG. 1C illustrates the electrical connection 116a is made only to an outer edge trace 102a, while island traces 102b are electrically disconnected from each other and the outer edge trace, as schematically shown in FIG. 1C. In FIG. 1C, the power supply 114 is on and showing a current flowing to the outer edge trace 102a, which makes the trace the anode 108. FIGS. 1D and 1E illustrate when the electro-deburring, electro-polishing, or PeP is performed by applying a voltage, only the burrs 104a present on the outer edge trace 102a of the laser-micromachined PCB traces are deburred, while the burrs 104b present on the island traces 102b are not deburred. FIG. 1F illustrates the traditional electro-deburring process is not suitable for deburring laser-micromachined PCB traces, because the island traces 102b cannot be deburred using the process, and only the outer edge trace 102a is deburred.

In some embodiments, provided is a novel process to deburr laser-etched or laser micromachined PCB traces (e.g., deburring PCB traces that are electrically isolated).

In some embodiments, a method includes the following steps.

In the first step, the PCB traces are formed on an insulating layer 206, as metal-insulator laminate by patterning the top metal layer using the laser micromachining process. A trace width 203 is determined by the laser toolpath, and an intertrace spacing 205 is determined by a laser spot size utilized in the laser micromachining process. The smaller spot size can be used to achieve smaller intertrace spacing, and the larger spot size can be used to achieve a higher etch rate by changing the spot size in real time. Using the laser-etching or laser micromachining process, the PCB traces 202 can be formed on a variety of insulating layer 206 substrates such as FR4, polyimide, glass, ceramic, silicon, etc.

In the second step, a thin-film conducting layer 207 is deposited on the laser-micromachined PCB as shown in FIG. 2B. The thin film conducting layer 207 can be selected from any suitable conducting material, selected from the group consisting of copper, liquid metal ink, graphite, and the like. The thin-film conducting layer 207 can be deposited on the PCB traces 202 and insulating layer 206 substrate using a deposition process, selected from the group consisting of electroless plating, physical vapor deposition (PVD), sputtering, chemical vapor deposition (CVD), atomic layer deposition (ALD), spin-coating, spray-coating, dip-coating, or similar methods. The thin film conducting layer 207 can be of the same material as the PCB traces 202, or it can be selected from a different conducting material. The thin film conducting layer 207 electrically connects all or most of the isolated PCB traces 202b and provides an electrical connection (or flow of current) for electrolytic deburring. The deposited thin-film conducting layer 207 may not need to be uniformly coated over the laser-micromachined PCB if there is sufficient overlay of the conductive material to provide electrical connections with all or most traces 202 and particularly isolated PCB traces 202b.

In a third step, the method includes making an anodic electrical connection to the thin film conducting layer 207 to perform electrolytic deburring (e.g., see FIG. 2C). The electrical connection can be made to the thin-film conducting layer 207 at multiple points using an array of electrodes spanning the PCB area to ensure a uniform voltage is applied across the thin-film conducting layer 207 and provide a low resistance electrical connection to traces 202 and isolated PCB traces 202b.

In a fourth step, electrolytic deburring is performed (e.g., see FIG. 2D) using an electro-deburring process, plasma electrolytic polishing (e.g., see FIG. 2F), or electro-polishing. The electro-deburring or electropolishing process can be used when the thin film conducting layer 207 is selected from the same material as the PCB trace 202. Electro-deburring can be used when burrs 204 are larger, while electro-polishing is used when burrs 204 are comparable to the surface roughness of PCB traces 202.

In some embodiments, plasma electrolytic polishing is used when the thin-film conducting layer 207 material is different than the PCB trace 202 material or when the resistance of the thin-film conducting layer 207 or PCB traces 202 is higher than the resistance for the electro-deburring or electro-polishing process. Plasma electrolytic polishing uses higher voltage than electro-deburring or electro-polishing and it can be less sensitive to a change in resistance of the thin film conducting layer 207 compared to electro-deburring and electro-polishing processes. Plasma electrolytic polishing also offers high selectivity for removing burrs 204 without etching away the thin film conducting layer 207 because there is no anodic dissolution of anode (e.g., PCB traces) in the plasma electrolytic polishing. The plasma electrolytic polishing also uses an environmentally friendly electrolyte 212.

In some embodiments of the method, an electro isle deburring voltage waveform is used.

For certain conducting coating materials, it is possible that the thin-film conducting layer 207 can be partially removed due to a chemical reaction between the thin-film conducting layer 207 and the electrolyte 212 used for deburring, or due to the anodic dissolution caused by an electro-deburring or electropolishing process (e.g., see FIG. 2G). The reduction in the thickness of thin-film conducting layer 207 can be estimated by measuring the resistance of the thin-film conducting layer 207 or using optical inspection.

For such materials, the thickness of the thin-film conducting layer 207 can be increased by reversing the electrochemical cell voltage and performing an electroplating over the thin-film conducting layer 207 as schematically shown in FIG. 2H. In the electroplating cycle, cell parameters, such as voltage, current, duration, electrode configuration, and electrolyte flow, are set to maximize a uniform electroplating of the thin-film conducting layer 207, while in the deburring cycles, these parameters are set to maximize selective electrochemical etching of burrs 204 without etching away the thin-film conductive layer 207. For example, during the electroplating cycle, a low-voltage and a larger separation between the electrodes can be used to perform uniform plating, while during the electro isle deburring, a high voltage and a short separation between the electrodes is used to perform plasma electrolytic polishing and selectively remove burrs 204. The electroplating can also be performed in a separate electrochemical cell using an electrolyte 212 different than the deburring electrolyte 212.

Monitoring a deburring current is used to determine when the burrs 204 are removed. The deburring current is larger when more burrs 204 are present, and slowly reduces as the burrs 204 are removed. The deburring current saturates to a low value when all or most burrs 204 are removed. Alternatively, or in addition, an optical inspection system inside the electrochemical cell can also be used to determine when all or most burrs 204 are removed. After the deburring, burrs 204 can also be inspected using other inspection techniques and apparatus, such as an optical profilometer, a scanning electron microscope, an x-ray, and the like, to ensure all or most of the burrs 204 are removed. If there are some burrs 204 remaining, the PCB substrate may be deburred again.

In a fifth step, once all or most of the burrs 204 are removed (e.g., see FIG. 2I), the thin film conducting layer 207 is removed using a flash wet chemical etching, a plasma etching, or similar methods, such that PCB traces 202 are electrically isolated (e.g., see FIG. 2J). Since the thin-film conducting layer 207 is much thinner than the thickness of the PCB trace 202, the thin-film conducting layer 207 is etched away more rapidly without significantly affecting the PCB traces 202. Also, the thickness of the thin film conducting layer 207 can be reduced using uniform anodic dissolution before etching. FIG. 2K shows the electro isle deburred PCB traces 222. Also, the gap G between the PCB traces can be filled with an insulating material.

In some embodiments, for certain conducting materials or deposition processes, the deposited thin-film conducting layer 207 may not coat uniformly over the laser-micromachined PCB and certain PCB traces 202 may remain electrically isolated. In such situations, multiple cycles of applying the thin film conducting layer 207 material, followed by electro isle deburring may be performed to cover all or most PCB traces 202.

In some embodiments, in the fourth step, burrs 204 are removed using an electro-deburring process.

In some embodiments, in the fourth step, the burrs 204 are removed using an electro-polishing process.

In some embodiments, in the fourth step, burrs 204 are removed using the PeP process (e.g., see FIG. 2F). The voltage used for PeP is higher than the voltage used for the electro-deburring or electro-polishing process. The high voltage creates a plasma skin around the burrs 204, resulting in plasma etching of the burrs. The burrs 204 have sharp edges and create a higher plasma discharge than smooth areas of the PCB traces 202, and thus become selectively etched.

In some embodiments, a combination of plasma electrolytic polishing, electro-deburring, and electro-polishing is used to remove burrs 204 from laser-etched or laser-micromachined PCB traces 202.

In some embodiments, for certain thin-film conducting layer 207 material, it is possible that the thin-film conducting layer 207 can be partially removed due to a chemical reaction between the thin-film conducting layer 207 and the electrolyte 212 used for deburring, or due to the anodic dissolution caused by the electrolytic deburring process. For such materials, the thickness of the thin-film conducting layer 207 may be increased by reversing the electrochemical cell voltage and performing electroplating over the thin-film conducting layer 207.

During a positive cycle of the power supply 214 voltage, the PCB traces 202 are deburred, while in the negative cycle of the power supply 214 voltage, the electroplated material is uniformly deposited over the thin film conducting layer 207. Note that deburring uses selective etching of burrs 204, while electroplating uses uniform deposition of the thin film conducting material.

In the electro isle deburring cycle, electrochemical cell parameters such as the voltage, current, pulse duration, voltage or current waveform, electrode configuration, electrolyte flow, electrolyte concentration, bath temperature, etc. are set to maximize deburring (e.g., selective removal of burrs 204 without etching other parts of the traces 202). While in the electroplating cycle, these parameters are set to ensure a uniform electroplating. One example of such change in parameters is using high-voltage and bringing electrodes close to each other to perform deburring and using low-voltage and far-apart electrodes to perform uniform electroplating.

In some embodiments, if the electrolyte 212 used for deburring is different than the electrolyte 212 used for electroplating then the laser-micromachined PCB can be moved to a different cell for electroplating. After the electroplating, the PCB is moved back to the deburring cell for the electro isle deburring process.

An example implementation of the steps is shown in FIGS. 2A to 2K. FIG. 2A illustrates PCB with laser-micromachined traces 202 showing burrs 204 present at the traces 202 due to laser micromachining, in accordance with some embodiments of the present disclosure. The laser-micromachined traces 202 include an outer edge trace 202a and electrically isolated isle traces 202b. The PCB includes an insulating layer 206.

FIG. 2B illustrates a thin-film conducting layer 207 being deposited on the laser-micromachined PCB 200, including being deposited on the traces 202, burrs 204, and the insulating layer 206. The thin film conducting layer 207 can be deposited using PVD, CVD, ALD, electroless copper, liquid metal ink, or similar methods, in accordance with some embodiments of the present disclosure.

FIG. 2C illustrates electroplating being used to increase the thickness of the thin film conducting layer 207 or to deposit a different conducting coating over the layer deposited in FIG. 2B, in accordance with some embodiments of the present disclosure.

FIG. 2D illustrates electro-deburring being performed by applying a positive voltage at PCB traces 202 (acting as anode) and a negative voltage at the cathode, in accordance with some embodiments of the present disclosure. The value of the voltage depends on the deburring material and electrolyte 212 selected. The thin film conducting coating 207 provides an electrical connection to all or most isolated traces 202b for electro-deburring, electropolishing, or PeP processing.

FIG. 2E illustrates a schematic diagram showing deburring of all or most PCB traces 202 using electro-deburring or electropolishing, in accordance with some embodiments of the present disclosure.

FIG. 2F illustrates an alternative to or in combination with the process shown in FIG. 2E, in which the burrs 204 can also be removed using a plasma electrolytic polishing process, in accordance with some embodiments of the present disclosure. The high voltage power source 215 provides a voltage used for PeP that is higher than the voltage used for electro-deburring or electro-polishing process. The burrs have sharp edges, and the high voltage creates plasma discharge 217 around the burrs 204, resulting in plasma etching of the burrs.

FIG. 2G illustrates the electro isle deburring process selectively etches the burrs 204 without significantly affecting the other parts, in accordance with some embodiments of the present disclosure. For certain conducting coating materials, the electrolytic electro-deburring process can reduce the thickness conductive coating of the thin film conducing layer 207, schematically shown in FIG. 2G. FIG. 2G shows the partially etched away burrs 204a as well as the reduced conductive coating material 207a.

FIG. 2H illustrates the condition where the voltage is reversed at power source 214 to perform electroplating and increase the thickness of the coating resulting in a thickened coating 207b or a regenerated conductive coating. Note that the voltage, current, and other electrochemical cell parameters value for electroplating is different from electro isle deburring, in accordance with some embodiments of the present disclosure. In the example, the traces 202 or the coating 207b become the cathode and the PCB 210 becomes the anode.

FIG. 2I illustrates a schematic diagram showing the completion of the electro isle deburring process, in accordance with some embodiments of the present disclosure. In the process, the voltage is changed as well as the polarity for electro-deburring, electropolishing, or plasma electrolytic polishing. Also, the traces 202 are almost completely deburred or completely deburred.

FIG. 2J illustrates that after the electro isle deburring process, the thin film conducting layer 207 is removed using chemical etching that includes using an etchant 220, in accordance with some embodiments of the present disclosure.

FIG. 2K illustrates a schematic diagram showing electro isle deburred PCB 222 with deburred traces 202, in accordance with some embodiments of the present disclosure.

In some embodiments, fabricating multi-layer PCB manufacturing using the above processes is used. In some embodiments, making multi-layer PCBs using the above laser micromachining and electro isle deburring process is used.

For example, making multi-layer PCBs can be done according to the steps shown in FIGS. 3A to 3O.

FIG. 3A illustrates a first conductor-insulator laminate used as a substrate for PCB layer-by-layer buildup. The first conductor-insulator laminate includes a first conducting layer 302, in accordance with some embodiments of the present disclosure. The first conducting layer 302 can be conductive metals (for example, copper), a conducting polymer, etc., deposited on an insulating material 304. The insulating material 304 may be selected from the group consisting of ceramic, FR4, and glass.

FIG. 3B illustrates PCB traces 306 and alignment marks 308 formed on the conducting layer 302 using laser micromachining followed by an electro isle deburring process, in accordance with some embodiments of the present disclosure. The PCB layer is a composite of the conducting layer 302, the insulating material 304, and the PCB traces 306, and may be referred to herein as the first PCB layer.

FIG. 3C illustrates the gaps G between the PCB traces 306 are filled with one or more of a dielectric 310 and/or an insulator material 310.

FIG. 3D illustrates a superjacent conductor-insulator layer (the second PCB layer) formed on top of the first or preceding conductor-insulator layer. The second PCB layer includes a superjacent conducting layer 302′, a superjacent insulating layer 304′, a superjacent cut-out 312 placed to overlie alignment marks 308 of a subjacent conductor-insulator laminate. The superjacent conductor-insulator layer is laminated over the subjacent conductor-insulator layer. In this instance, the second PCB layer is laminated over the first PCB layer, in accordance with some embodiments of the present disclosure.

FIG. 3E illustrates vias 314 that may be drilled using the laser micromachining process, in accordance with some embodiments of the present disclosure. The vias 314 stop at the conducting layer 302 of the first PCB layer and are used for making electrical connections between the superjacent conductor-insulator layer and the subjacent conductor-insulator layer. In the embodiment shown, the vias 314 provide an electrical conductivity path between the superjacent conducive layer 302′ and the subjacent conductive layer 302. The electrolytic deburring process may also be used to remove the burrs (not shown) from the vias 314.

FIG. 3F illustrates a thin conducting seed layer 318 deposited to cover via hole walls 314, subjacent conducting layer 302, and superjacent conducting layer 302′, in accordance with some embodiments of the present disclosure. The thin conducting seed layer 318 can be deposited using electroless plating, atomic layer deposition (ALD), or other deposition methods.

FIG. 3G illustrates utilization of electroplating to apply a thicker conducting layer 320 over the initial thin conducting seed layer 318 to increase conductance, in accordance with some embodiments of the present disclosure. The metal of the thicker conducting layer 320 is deposited at the vias walls provides the electrical connection between the subjacent, first PCB layer, and the superjacent, second PCB layer.

FIG. 3H illustrates superjacent traces 306′ are formed using laser micromachining followed by electro isle deburring, as previously described, in accordance with some embodiments of the present disclosure.

FIG. 3I illustrates the gaps G′ between the superjacent PCB traces 306′ being filled with a dielectric and insulator material 324, in accordance with some embodiments of the present disclosure.

FIGS. 3J to 3N illustrate that subsequent PCB layers may be formed by repeating the steps described in FIGS. 3D to 3H. The vias 314 can also be drilled between multiple PCB layers, as shown in FIG. 3K, in accordance with some embodiments of the present disclosure.

FIG. 3O illustrates a completely manufactured multi-layer PCB after removing the excessive area containing the alignment marks 308 and overlying cutouts 312, in accordance with some embodiments of the present disclosure.

In some embodiments, the layer-by-layer PCB buildup using the laser micromachining and electro isle deburring processes include the following steps.

In the first step, the method starts with a conductor-insulator dielectric rigid or flex substrate (e.g., see the conducting layer 302 and the insulating layer 304 shown in FIG. 3A). As previously indicated, the conducting layer 302 can be copper or other conducting material, and the insulator layer 304 can be glass, FR4, ceramic or other insulating material. The conducting layer 302 can be used to fabricate traces 306 using laser micromachining followed by electro isle deburring.

A second step includes using laser micromachining to machine alignment marks 308 and machine the traces 306 on the conducting layer 302. Next, use the electro isle deburring process to remove burrs from the laser-micromachined PCB traces 306 (e.g., see FIG. 3B). The layer is henceforth known as the first PCB layer.

A third step includes filling the gap G between the PCB traces 306 with dielectric material 310 (e.g., see dielectric material 310 shown in FIG. 3C). Also, the step can be omitted to create PCB traces 306 with air gaps between them.

A fourth step includes laminating a conductor-insulator laminate layer (the second PCB layer) with a cut-out window 312 for alignment marks on the first PCB layer (e.g., as shown in FIG. 3D).

A fifth step includes using the alignment mark 308 in the first PCB layer visible through the cut-out 312 of the second PCB layer to align the second PCB layer design to the first PCB layer. Next, use the laser micromachining process to form one or more vias 314 in the second PCB layer, which stops at the conducting layer of the first PCB layer as schematically shown in FIG. 3E (e.g., see hole stop 316).

A sixth step includes applying a thin conducting layer 318 over the second PCB layer and vias 314 while masking alignment marks 308 on the first PCB layer (e.g., see FIG. 3F). The thin conducting layer 318 can be of any conducting material (for example, copper, liquid metal ink, conducting polymer, etc.) and can be deposited using various deposition processes such as electroless plating, PVD, sputtering, CVD, ALD, spin-coating, spray-coating, dip-coating, or similar methods. Also, an electroplating may be used to apply a thicker conducting layer 320 over the thin conducting layer 318 (see FIG. 3G) to increase conductance of the one or more vias 314. The metal deposited at the one or more via walls creates an electrical connection between the first PCB layer and the second PCB layer (e.g., see via fill 322).

A seventh step includes using laser micromachining to machine the traces 306′ on the superjacent conducting layer 320 of the second PCB layer and using the disclosed electro isle deburring process to remove burrs (not shown) from the laser-micromachined PCB traces (e.g., see FIG. 3H). Also, the gap G between traces may be filled using dielectric material 324 as shown in FIG. 3I. The subsequent superjacent PCB layers are built by repeating the steps shown in FIGS. 3J to 3N. Note that during the layer buildup, the one or more vias 314 can be formed between multiple layers, as shown in FIG. 3K. The layer stack-up of a four-layer PCB is schematically shown in FIG. 3N. Also shown in FIG. 3N is the PCB with deburred traces 326.

An eighth step includes, once the layer buildup is complete, cutting the PCB to dimensions and removing the region containing the alignment mark 308. FIG. 3O shows the completed ultra-high-density multi-layer PCB after a cut has been made to the PCB to the dimension and the region containing the alignment marks 308 is removed.

In the traditional PCB layer buildup process, the new superjacent layers are aligned with respect to the alignment mark located on the top layer of the PCB layer buildup. Thus, the layer alignment error increases with an increasing layer count. However, in the method disclosed, every layer can be aligned with respect to the same alignment mark 308 that is located in the first layer. Thus, the errors are not aggregated as the layer count increases.

In some embodiments, PCB traces 306, 306′, . . . 306″ with air gaps are used.

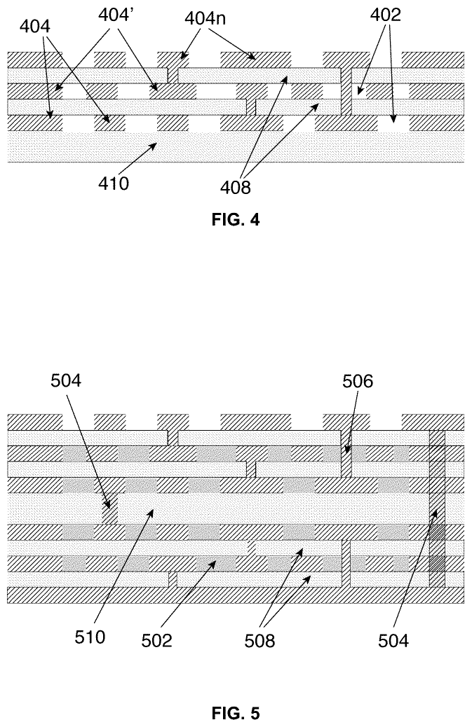

In some embodiments, the step shown in FIG. 3C is omitted, thereby creating PCB traces 404, 404′, . . . 404″ with air gaps 402 between them (e.g., see FIG. 4). The example eliminates thermal and electrical issues associated with the dielectric material 310 used to fill the gap 402 between the PCB traces 404, 404′, . . . 404ⁿ. Moreover, since air has the lowest dielectric constant, it enables fast data propagation speed in the PCB traces 404, 404′, . . . 404ⁿ. These PCBs with airgap between the traces 404, 404′, . . . 404ⁿ are suitable for high-density interconnects in heterogeneous integration of chiplets.

In some embodiments, layer-by-layer buildup on both sides of core laminate (see FIG. 5) is used.

In some embodiments, the vias 314 are drilled in conducting-insulator laminate before lamination, which allows machining vias 314 of different shapes. In FIG. 3D, the conducting-insulator laminate (302′ 304′) is first laminated and then in FIG. 3E, the vias are drilled. This method only allows for drilling via's from the top result in vias that are wider on top and narrow as they go deeper (not shown in image). The via shown in image has vertical wall). However, if the via's 314 are drilled first in conducting-insulator laminate 302′ 304′) this allows drilling from both a top and a bottom and can be used to create vias 314 that are 1) wide on top and narrow on bottom, or 2) narrow on bottom and wide on top). After drilling the vias 314, it is laminated. In summary, in one embodiment step FIG. 3D (laminate first) is before step FIG. 3E (then drill via) and in other embodiment step FIG. 3E (drill first) is before FIG. 3D (then laminate).

In some embodiments, the disclosed laser-etching or laser micromachining followed by electro isle deburring is used in conjunction with the traditional wet-chemical etching or semi-additive process. First, large trace width and spacing PCB traces 404, 404′, . . . 404″ are formed using the traditional wet-chemical etching or semi-additive process. For traces that are too small to be made using traditional PCB manufacturing processes, the traces are left connected and later laser micromachined followed by electro isle deburring is used to form these small traces. This allows for the use of traditional PCB manufacturing process to create large traces and then utilize laser-micromachining process of the present invention to create small traces. This allows the benefit of high throughput provided by existing technologies as well as small trace width and spacing provided by aspects of the present invention.

Also, using laser micromachining, smaller trace width, and spacing, traces 404, 404′, . . . 404ⁿ can be machined and deburred using the electro isle deburring process.

Also, multi-layer PCBs can be made using some of the methods disclosed herein or using the standard PCB manufacturing processes.

For example, FIG. 4 shows a multi-layer PCB with airgap 404 between the traces 402 for high-speed applications, in accordance with some embodiments of the present disclosure. Also, FIG. 4 shows a multi-layer PCB with airgap 404 between the traces 402, in accordance with some embodiments of the present disclosure. Since air has the lowest dielectric constant, it enables the fast data propagation speed in the PCB traces. These PCBs are suitable for high-density interconnects in heterogeneous integration of chiplets. Also, FIG. 4 shows vias 406 connecting the traces, insulating layers 408 between the traces, and the core 410 of the PCB.

Also, for example, FIG. 5 shows PCB layer buildup on both sides of the PCB core and with the air gaps filled with dielectric material 502, in accordance with some embodiments of the present disclosure. In the example of FIG. 5, the vias include mechanical machined vias 504 providing conduction through the core 510, and laser-micromachined vias 506 providing conduction through the insulating layers 508.

The advantage of the process described in the example embodiment is that the traditional process can be used for low-density PCB traces and layers, while the disclosed PCB manufacturing process can be used to fabricate high-density traces and layers. A use case for example is in the fabrication of PCB substrate for mounting electrical circuit components with or without a high-density ball grid array (BGA) fan-out. Known PCB manufacturing processes can be used to pattern low-density PCB traces and layers, and laser micromachining can used to pattern BGA pads and high-density traces and layers.

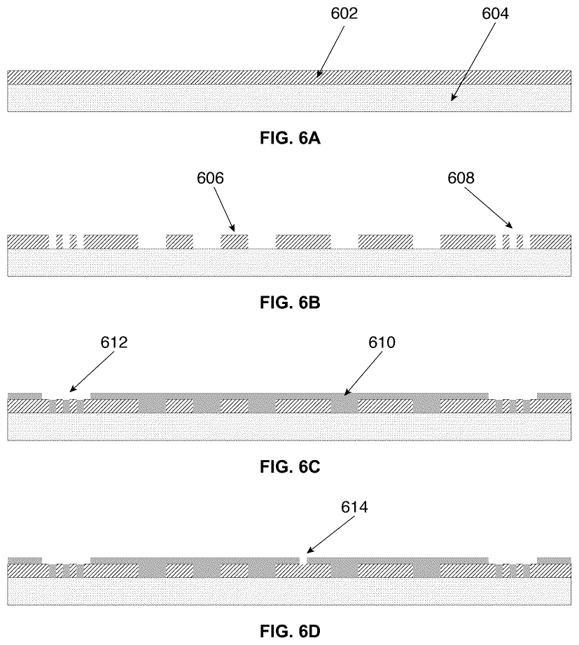

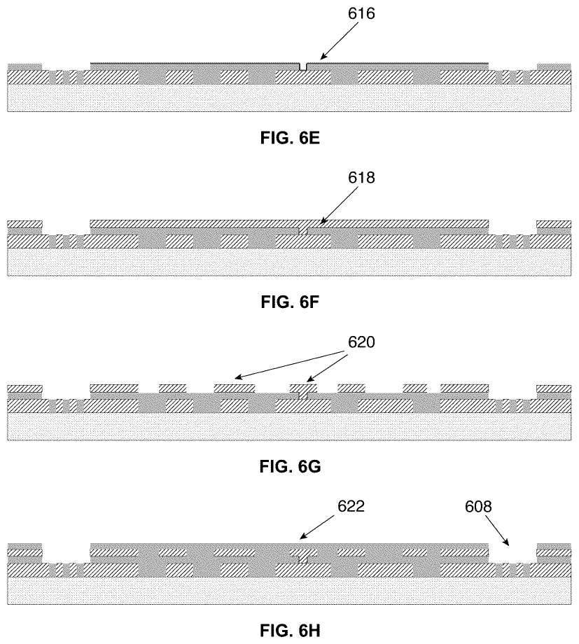

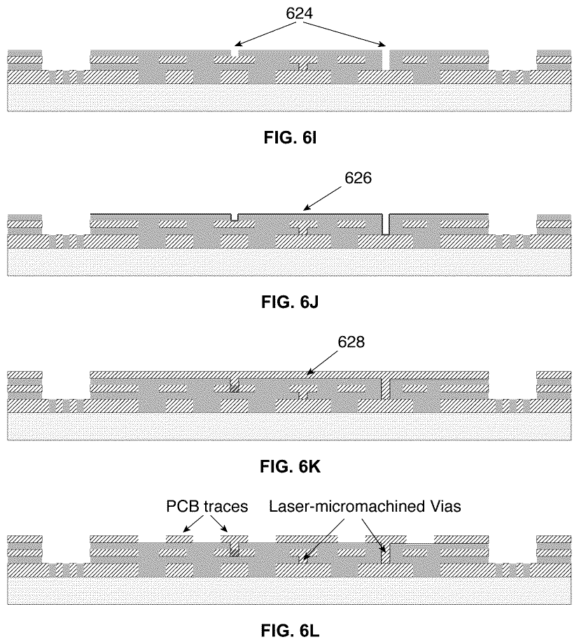

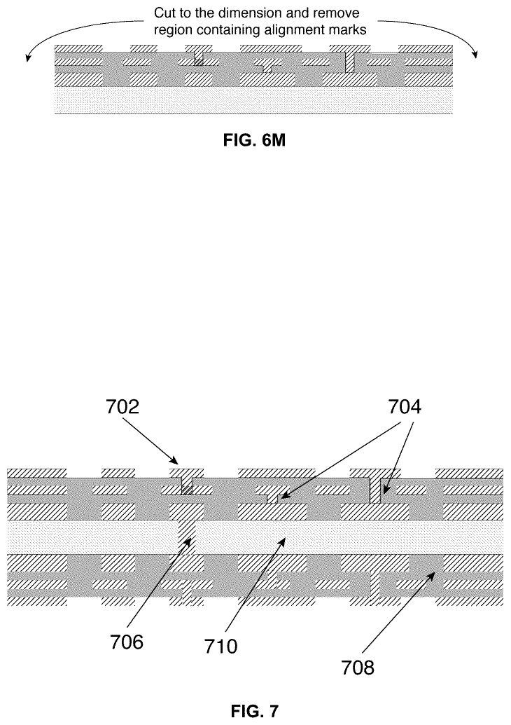

For example, FIGS. 6A to 6M show separate process steps for manufacturing PCBs by depositing dielectric and conducting layers and using laser micromachining followed by electro isle deburring to define PCB traces and are provided in order of operation sequence starting with the step in FIG. 6A and ending with the step in FIG. 6M, in accordance with some embodiments of the present disclosure.

FIG. 6A illustrates a conductor-insulator laminate used as the substrate for PCB layer-by-layer buildup, in accordance with some embodiments of the present disclosure. The conductor-insulator laminate includes a conducting layer 602 that can be formed of metals (for example, copper), conducting polymer, etc., deposited on an insulating material 604, which can be formed of a ceramic, FR4, glass, etc.

FIG. 6B illustrates using laser micromachining followed by electro isle deburring to make PCB traces 606 and alignment marks 608 on the conductor-insulator either of a rigid or a flex substrate, in accordance with some embodiments of the present disclosure.

FIG. 6C illustrates depositing a dielectric material to define a dielectric layer 610 (such as liquid polyimide, etc.) over the previous layer (PCB traces) while masking the alignment mark region 608 which includes providing a window 612 for exposing the alignment marks 608, in accordance with some embodiments of the present disclosure. In constructing a PCB stack, the insulating (also called dielectric) layer 610 is deposited over the previous traces to separate the traces from a previous layer the conducting layer traces that will be applied to the dielectric layer 610 in a subsequent layer of the PCB stack.

FIG. 6D illustrates drilling vias 614 using laser micromachining, making sure the hole stops at the subjacent PCB traces 606 where an electrical connection is desired, in accordance with some embodiments of the present disclosure. Using the alignment marks 608 in the first layer visible through the window 612 in the dielectric layer 610 to align the via 614 with the bottom layer and determine the location of the vias 614 in the overlying conductive layer 610.

FIG. 6E illustrates the depositing of a thin film conducting layer 616 (or seed layer) over the dielectric layer 610 and via hole 614 while masking the alignment mark 608 region. Various deposition methods, such as electroless plating, PVD, sputtering, CVD, ALD, spin-coating, spray-coating, dip-coating, or other deposition methods can be used to deposit the conducting layer 618.

FIG. 6F illustrates using electroplating to plate conducting material 618 over seed layer 616 to increase the thickness of the thin film conducting layer 616, in accordance with some embodiments of the present disclosure.

FIG. 6G illustrates the use of laser micromachining followed by electro isle deburring to make PCB traces 620 on the conducting layer 618 deposited in the previous step.

FIGS. 6H to 6L illustrate building subsequent PCB layers by repeating the steps shown in FIGS. 6C to 6G, in accordance with some embodiments of the present disclosure.

FIG. 6H illustrates depositing dielectric material 622 (such as liquid polyimide, etc.) over the previous layer (PCB trace layer) while masking the alignment mark 608 region, in accordance with some embodiments of the present disclosure.

FIG. 6I illustrates drilling vias 624 using laser micromachining. Note that during the layer buildup, the vias 624 can be formed between multiple layers, as shown in FIG. 6I, in accordance with some embodiments of the present disclosure.

FIG. 6J illustrates depositing a thin film conducting layer 626 (or a seed layer) over the dielectric layer 626 and via 624 holes while masking the alignment mark region, in accordance with some embodiments of the present disclosure.

FIG. 6K illustrates using electroplating to plate conducting material 628 over the seed layer 626 to increase the thickness of the conducting layer, in accordance with some embodiments of the present disclosure. The layer stack-up of a three-layer PCB is schematically shown in FIG. 6L.

FIG. 6M illustrates that once the layer buildup is complete, the process can include cutting the PCB to dimensions and removing the region containing the alignment mark 608 and the overlying alignment cut-out 612. FIG. 6M schematically shows the completed ultra-high-density multi-layer PCB, in accordance with some embodiments of the present disclosure.

In some embodiments, the PCBs may be provided with a liquid polymer as a dielectric layer and an electrodeposited conducting material over one or more PCB trace layers. In the example, the conducting layer is electrodeposited conducting material, and the insulating layer is a liquid polymer. The process of building a multi-layer PCB includes the following steps.

First, the process includes the use of laser micromachining followed by electro isle deburring to make PCB traces 606 and alignment marks 608 on the conductor-insulator formed as a rigid or a flex substrate as shown in FIG. 6B.

Second, the process includes depositing polymer insulator and dielectric material film 610 (such as liquid polyimide, etc.) over the previous layer while masking the alignment mark 608 region as shown in FIG. 6C.

Third, the process includes drilling one or more vias 614 using laser micromachining, making sure the vias 614 terminate at a desired PCB trace layer where an electrical connection is desired (e.g., see FIG. 6D). Use the alignment marks in the first layer visible through the cut-out 612 in the dielectric layer 610 to align the via hole design files with the alignment marks 608 on the bottom layer of the PCB structure and determine the location of the vias 614.

Fourth, the process includes depositing a thin film conducting layer 616 (or seed layer) over the dielectric layer 610 and via 614 while masking the alignment mark 608 region as shown in FIG. 6E. As described previously, various deposition methods, such as electroless plating, PVD, sputtering, CVD, ALD, spin-coating, spray-coating, dip-coating, or other deposition methods can be used to deposit the conducting layer. In some cases, electroplating to plate conducting material 618 over the seed layer 616 to increase the thickness of the conducting layer is used as shown in FIG. 6F. In some examples, laser micromachining followed by electro isle deburring to make PCB traces 620 on the conducting layer deposited in the previous step can be used, as shown in FIG. 6G. To build subsequent PCB layers, repeat the steps shown in FIGS. 6C to 6G. Note that during the layer buildup, the vias 614 can be formed between multiple layers, as shown in FIG. 6G.

The layer stack-up of a three-layer PCB is schematically shown in FIG. 6L. Once the layer buildup is complete, the PCB is cut to the dimension, and the region containing alignment marks 608 is removed. FIG. 6M shows the completed ultra-high-density multi-layer PCB. As will be appreciated, the process can also be used to build PCB layers on both sides of a core of the high-density multi-layer PCB, as shown in FIG. 7. In this instance, the core 700 may be a single or a double thickness of the insulating material 604 for a single sided PCB structure.

In some embodiments, double-sided PCBs are used. For example, FIG. 7 shows PCB layers buildup on both sides of the core 710, in accordance with some embodiments of the present disclosure. The PCB layers include traces 702, laser-micromachined vias 704, mechanically machined vias 706, dielectric material 708, and core 710. Also, FIG. 7 shows PCB layers buildup on both sides of the core 710 by depositing dielectric and conducting layers and using laser micromachining followed by electro isle deburring to define PCB traces 702, in accordance with some embodiments of the present disclosure.

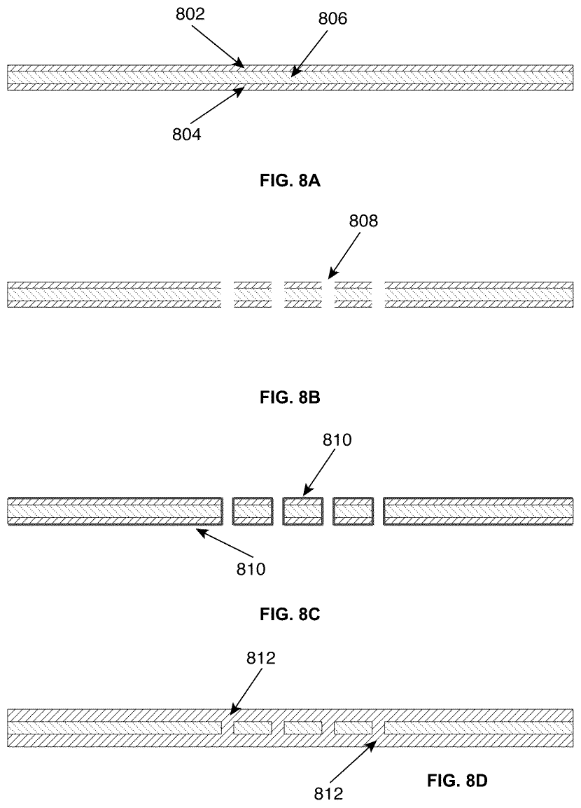

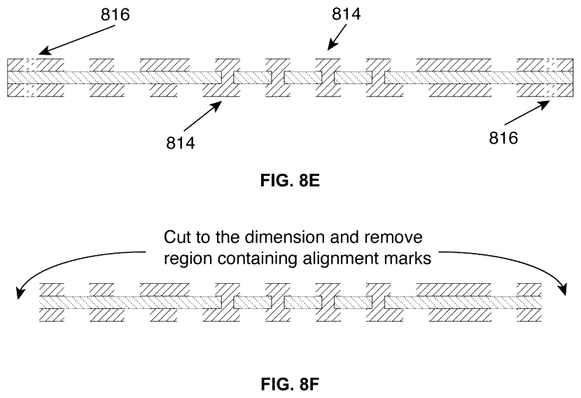

FIGS. 8A to 8F are each separate process steps for fabricating high density double-sided PCB 800 and are provided in order of operation sequence starting with the step in FIG. 8A and ending with the step in FIG. 8F.

FIG. 8A illustrates starting with a double-sided conductor-insulator-conductor rigid or flex laminate, in accordance with some embodiments of the present disclosure. The double-sided conductor-insulator-conductor laminate includes a first conducting layer 802, a second conducting layer 804, and an insulating layer 806 in between the conducting layers. The first conducting layer 802 is deposited on the first side of the insulating layer 806. The second conducting layer 804 is deposited on a second side of the insulating layer, opposite the first side of the insulating layer 806.

FIG. 8B illustrates drilling vias 808 using laser micromachining. Use electro isle deburring to remove burrs (not shown) from vias 808, as previously described in the other embodiments.

FIG. 8C illustrates the deposition of a thin film conducting layer 810 (or seed layer), On each of the first conducting layer 802, the second conducting layer 804, and the vias 808. Various deposition methods, such as electroless plating, PVD, sputtering, CVD, ALD, spin-coating, spray-coating, dip-coating, or other deposition methods can be used to deposit the thin-film conducting layer 810.

FIG. 8D illustrates using electroplating to plate a conducting material 812 over the thin-film conducting layer 810 to increase the thickness of the thin-film conducting layer 810 and fill vias 808.

FIG. 8E illustrates the use of laser micromachining followed by electro isle deburring to make PCB traces 814 and alignment marks 816, in the dual sided PCB 800.

FIG. 8F illustrates cutting the PCB to dimension and removing the region containing the alignment marks 816. FIG. 8F schematically shows the completed ultra-high-density two-layer PCB 800, in accordance with some embodiments of the present disclosure.

In some embodiments, the high density dual-layer PCB 800 is fabricated using the following process shown in FIGS. 8A to 8F as well. First, drill vias 808 on a conductor-insulator-conductor rigid or flex laminate using laser micromachining as shown in FIG. 8B. Use electro isle deburring, as previously described, to remove burrs (not shown) from the vias 808. Second, the method includes depositing a thin-film conducting layer (or a seed layer) 810 as shown in FIG. 8C. Various deposition methods, such as electroless plating, PVD, sputtering, CVD, ALD, spin-coating, spray-coating, dip-coating, or other deposition methods can be used to deposit the thin-film conducting layer 810. Also, electrodeposition may then be applied to plate additional conducting material 812 over the seed layer 810 to increase the thickness of the conducting seed layer 810 and fill vias 808, as shown in FIG. 8D. The via 808 electrically connects the two conducting layers 802, 804 of the conductor-insulator-conductor laminate 800. Next, use laser micromachining, as previously described, followed by electro isle deburring to make PCB traces 814 and alignment marks 816 on both the first conducting layer 802 and the second conducting layer 804 as shown in FIG. 8E. Finally, cut the PCB 800 to dimension and remove the region containing the alignment mark 816. FIG. 8F shows the completed ultra-high-density dual-layer PCB 800.

In some embodiments, multi-layer PCBs with mechanical or laser vias 808 are used.

For example, double-sided PCBs are manufactured as described in the embodiment shown in FIGS. 8A to 8F. These double-sided PCBs 800 are laminated to create multi-layer PCBs. Vias 808 are created to electrically connect the respective PCB layers.

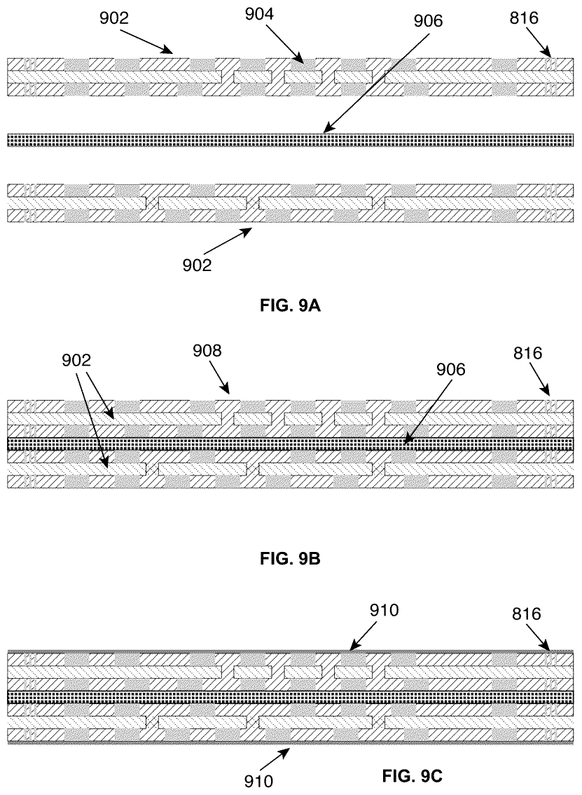

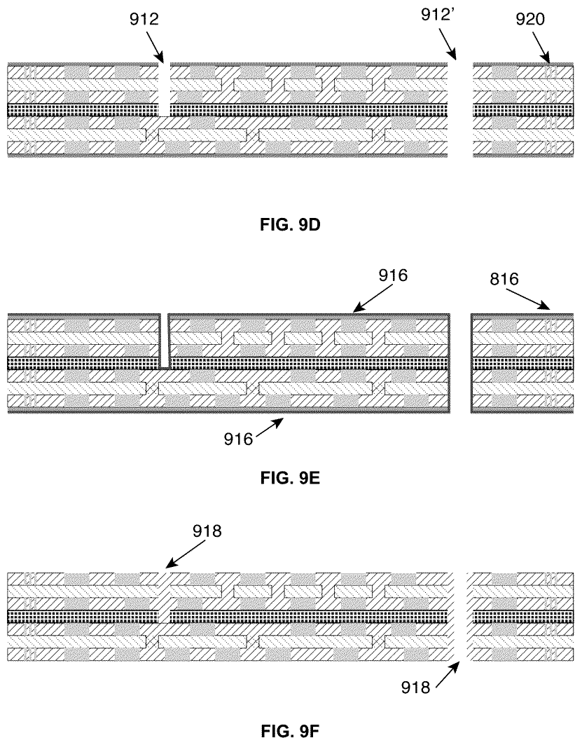

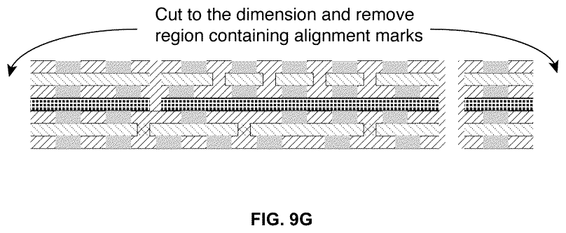

FIGS. 9A to 9G show separate process steps for fabricating a multi-layer PCBs 900 by laminating a double-sided PCB laminate and are provided in order of operation sequence starting with the step in FIG. 9A and ending with the step in FIG. 9G.

FIG. 9A illustrates alternative process steps described in FIG. 8 to make a double-sided PCB 900/and fill the gap between the traces 902 using dielectric material 904. For the layers using low-density PCB traces 902, the traces 902 can also be fabricated using traditional PCB manufacturing processes. Laminate double-sided PCBs are shown in FIG. 9A.

FIG. 9B illustrates a four-layer PCB 900 created by laminating two double-sided PCBs with one of an insulating layer 906 or a dielectric layer 906 interposed between a first PCB and a second PCB. An adhesive layer (not shown) may be applied to the one of the insulating layer 806 and the dielectric layer 906 to join the first PCB and the second PCB.

FIG. 9C illustrates the step of applying a protective coating or film 910 on both sides of the joined first PCB and second PCB, the PCB buildup. The protective coating or film 910 is applied to mask selected areas of one or more of the outer faces of the PCB buildup, to selectively apply a thin-film conductor 916, as further described below.

FIG. 9D illustrates drilling one or more vias 912, 912′ using laser micromachining or mechanical milling, as previously described. As will be appreciated, the one or more vias 912, 914 may extend into the PCB buildup to provide electrical conductivity between conducting layers on the first PCB layer or may extend through the PCB buildup to provide electrical conductivity between the first PCB layer and the second PCB layer.

FIG. 9E illustrates the deposition of the thin film conducting layer (or the seed layer) 916. The deposited thin film conducting layer 916 covers the one or more via 912, 912′ hole walls, as well as a protective coating 920, in accordance with some embodiments of the present disclosure.

FIG. 9F illustrates using electrodeposition to plate conducting material over the seed layer 916 to fill vias 912, 912′, in accordance with some embodiments of the present disclosure. Next, remove the protective coating 920, leaving conducting material only in the vias 912, 912′. The vias 912, 912′ provide electrical connections between the PCB trace layers 904.

FIG. 9G illustrates cutting the PCB to dimension and removing the region containing the alignment marks 816, in accordance with some embodiments of the present disclosure. FIG. 9G schematically shows the completed ultra-high-density two-layer PCB 900.

In this embodiment, first, use the process steps described in the previous embodiment shown in FIGS. 8A to 8F to make multiple double-sided PCBs 800 and fill the gap between the traces using dielectric material 906. For the layers using low-density PCB traces 902, the traces 902 can also be fabricated using traditional PCB manufacturing processes. Next laminate the double-sided PCBs 800 together including a dielectric material 904 and using dielectric and adhesive layer 906, as shown in FIG. 9A. The four-layer PCB 900 created by laminating the two double-sided PCBs 800 together is shown in FIG. 9B. Second, apply a protective coating 910 or film on both sides of the PCB buildup as shown in FIG. 9C. Third, drill vias 912, 912′ using laser micromachining (e.g., see laser-micromachined via 912) or mechanical milling (e.g., see mechanically milled via 912′) as shown in FIG. 9D. Fourth, deposit the thin-film conducting layer 916 on the opposed outer faces of the PCB buildup. The thin film conducting layer 916 can cover via hole walls, as well as protective coating 910 as shown in FIG. 9E. This embodiment may also use electrodeposition to plate additional conducting material over the seed layer and fill vias 912, 912′, as previously described. Next, remove the protective coating 920, leaving conducting material only in the vias 912, 912′ as shown in FIG. 9F. The vias 912, 912′ provide electrical connections between selected PCB trace layers 902. Finally, cut the PCB 900 to a selected dimension and remove the region containing the alignment mark 920. FIG. 9G shows the completed ultra-high-density four-layer PCB 900 after the PCB has been cut to a selected dimension and the region containing alignment marks 920 has been cut away.

In some embodiments, PCBs with three-dimensional traces may also be fabricated.

For example, a PCB with three-dimensional traces is described. First, a thin-film layer of conducting material 916 is embossed to create the desired three-dimensional shape. Second, the conducting material sheet with a three-dimensional structure is attached or laminated over an insulating substrate. Finally, laser micromachining is used to machine PCB traces on the embossed shape to create three-dimensional PCB traces and electro isle deburring is used to remove burrs produced during the laser micromachining process.

The traditional PCB manufacturing process is limited to creating two-dimensional PCB traces. However, the PCB manufacturing process disclosed in the example can be used to fabricate PCBs with three-dimensional traces. Such PCBs can be used to interconnect chiplets in 3D space.

In some embodiments, high-density and high-current carrying capacity PCBs are used. For example, the process for making PCB with a trace thickness of more than 100 μm is described. In the process, a thickness (thickness more than 100 μm) is laminated over an insulating substrate, such as FR4, glass, ceramic, etc. Next, laser micromachining is used to machine high-aspect (10:1 to 20:1) ratio gaps between the traces. Multi-layer PCBs can be fabricated following a similar process.

In traditional PC manufacturing processes using wet-chemical etching, etching 250 μm thick PCB traces also results in a 250 μm gap between the traces, thereby resulting in low-density traces. However, using the process described in the example, PCB traces that are 100 μm to 250 μm thick, but only 5 μm to 10 μm apart can be laser-micromachined, thereby enabling high-density as well as high-current carrying PCBs. These PCBs are especially useful as substrates for ASIC applications that use both high-density routing and high-current carrying traces.

It is important to understand that the burrs were the major obstacle in reducing trace width and spacing of PCB traces formed using laser micromachining. The disclosed methods and systems herein enable removing burrs, thereby enabling laser micromachining to make PCB traces with fine line width and spacing. By enhancing laser micromachining processes and using the disclosed electro isle deburring process, the trace width and spacing below sub-micrometers can be easily achieved.

In some embodiments, ultra-high-density and miniaturized PCBs can be used as substrates for advanced semiconductor packaging such as system-in-package (SiP), heterogeneous integration of chiplets, and fan-out packaging. In addition, our miniaturized PCBs can also be used in space-constrained devices such as mobile and wearable devices, for applications using controlled impedance traces such as 5G or 6G applications, modules, and high-density PCB flex cables.

The electro isle deburring process disclosed herein can be used to deburr island structures found in other applications, such as MEMS devices, micro-fluidics, and other micro-structures fabricated using other micro-fabrication processes such as micro-milling, EDM, etc.

Some advantages of some embodiments include that the disclosed PCB manufacturing process offers the following advantages over known PCB manufacturing processes. Also, the disclosed PCB manufacturing process can be used to manufacture ultra-high-density PCBs with ten times or more wiring density than PCBs manufactured using traditional processes. Also, the disclosed PCB manufacturing process can be used to manufacture PCB traces with vertical walls, thereby allowing better signal integrity. The traditional PCB manufacturing process makes PCB traces with trapezoidal cross-section, which results in signal loss at high-speed signal propagation. Also, the disclosed PCB manufacturing process offers tighter manufacturing tolerance than current technology, thereby enabling better control over the impedance of traces used for high data propagation applications such as 5G or 6G.

Also, the disclosed PCB manufacturing process can be used to make PCBs with a variety of materials such as metals, alloys, conducting polymers, etc. The traditional PCB manufacturing process uses wet chemical etching to make PCB traces and is currently limited to making PCBs using only copper. Also, the disclosed PCB manufacturing process can produce PCBs with air gaps between the traces. The air has the lowest dielectric constant, enabling the fastest data propagation through the PCB traces. Also, the disclosed PCB manufacturing process enables manufacturing high aspect ratio PCB traces (10:1 to 20:1), thereby enabling manufacturing PCBs that are both high density as well as high current carrying capacity. Also, the disclosed PCB manufacturing process is a chemical-free, environmentally friendly PCB manufacturing process that does not generate hazardous chemical waste and drastically reduces water consumption. The traditional PCB manufacturing process uses photolithography and wet chemical etching to make PCB traces, using various chemicals such as photoresists, developers, etchants, etc., and generates hazardous chemical waste, and consumes a lot of water and energy.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method of reducing one or more defects from multiple traces of a printed circuit board (PCB), comprising:
depositing a thin film conducting layer over at least some of the multiple traces formed on the PCB, the multiple traces being electrically isolated from each other, the thin-film conducting layer electrically connecting at least some of the one or more defects on the traces after the thin film conducting layer is deposited; and
applying an electrical current to the thin film conducting layer in a first polarity to reduce or eliminate the one or more defects on the multiple traces.

2. The method of claim 1, further comprising:
applying the electrical current to the thin-film conducting layer in a second polarity to achieve an electroplating of the thin-film conducting layer to increase a thickness of the of the thin-film conducting layer.

3. The method of claim 2, further comprising:
applying the electrical current to the thin film conducting layer in the first polarity to further reduce or eliminate the one or more defects on the multiple traces.

4. The method of claim 1, further comprising:
removing the thin-film conductive layer by one or more of an etching or a stripping.

5. The method of claim 3, wherein at least some of the one or more defects comprise burrs.

6. An electro isle deburring (EID) process to reduce or eliminate one or more defects occurring on one or more traces carried on a substrate of a printed circuit board (PCB), the one or more traces comprising at least some island traces electrically isolated from each other, the EID comprising:
depositing a conducting layer over the one or more PCB traces, the conducting layer electrically connecting at least some of the one or more PCB traces and at least some of the one or more defects; and
applying an electrical current to the conducting layer to reduce or eliminate the one or more defects in the one or more PCB traces.

7. The electro isle deburring (EID) process of claim 6, the step of applying the electric current further comprising:
connecting a power supply between a first contact on the PCB and a second contact on the PCB;
applying an electrolytic composition between the first contact, the one or more PCB traces, and the one or more defects to define an electrolytic cell; and
applying the electrical current in a first polarity to the electrolytic cell to reduce or eliminate the one or more defects in the one or more PCB traces.

8. The electro isle deburring (EID) process of claim 7, further comprising:
applying the electrical current in a second polarity to the electrolytic cell to provide an electroplating of the conductive layer.

9. The electro isle deburring (EID) process of claim 6, wherein a voltage for the electrical current is determined according to a composition of the PCB traces, the conducting layer, or a combination thereof.

10. The electro isle deburring (EID) process of claim 6, further comprising:
applying an electro-polishing to the PCB traces, comprising;
applying a voltage to an anodic contact of an electrolytic cell to form a high-resistance path between the anodic contact, an electrolyte, and a peak of the one or more defects of the one or more PCB traces; and
inducing a high current density at the peak of the one or more defects to dissolve the one or more defects at a higher rate than the one or more PCB traces.

11. The electro isle deburring (EID) process of claim 10, further comprising, applying the electro-polishing to the PCB traces when a size of the one or more defects is comparable with a surface roughness of the PCB traces.

12. The electro isle deburring (EID) process of claim 6, further comprising:
applying an electro-deburring to the PCB traces when the one or more defects is a burr; and
applying suitable voltage to an anodic contact of an electrolytic cell to induce a high current density at a sharpened peak of the one or more burrs to dissolve or reduce the one or more burrs at a higher rate than the one or more PCB traces.

13. The electro isle deburring (EID) process of claim 12, further comprising:
applying the electro-deburring to the one or more PCB traces, when the one or more burrs have a size comparable to or greater than a surface roughness of the one or more PCB traces.

14. The electro isle deburring (EID) process of claim 6, further comprising:
applying a plasma electrolytic polishing (PeP) to the one or more PCB traces; and
applying a high voltage to an electrolytic cell to create an electric discharge as a plasma arc at a sharpened peak of one or more burrs.

15. The electro isle deburring (EID) process of claim 6, wherein the step of depositing of the conducting layer is selected from the group consisting of: a physical vapor deposition (PVD), a sputtering, a chemical vapor deposition (CVD), an atomic layer deposition (ALD), a spin-coating, a spray-coating, a dip-coating, an electroless copper, a liquid metal ink, or a combination thereof.

16. The electro isle deburring (EID) process of claim 6, further comprising:
forming the one or more PCB traces over an insulating substrate.

17. The electro isle deburring (EID) process of claim 6, further comprising:
creating the PCB traces; and
for each layer of a plurality of layers of a multi-layer PCB:
repeating the creating of the one or more PCB traces; and
forming vias between the plurality of layers after the repeating of the creating of the PCB traces.

18. A method, comprising:
applying an electro isle deburring (EID) process to reduce or eliminate burrs occurring on laser micromachined printed circuit board (PCB) traces, at least some of the PCB traces being electrically isolated from each other, the EID process, comprising:
depositing a conducting layer over the PCB traces, resulting in the conducting layer electrically connects at least some of the PCB traces; and
applying an electrical current or voltage to the conducting layer to reduce or eliminate the burrs.

19. The method of claim 18, further comprising:
laser micromachining of the PCB traces.

20. The method of claim 19, comprising:
for each layer of a plurality of layers of a multi-layer PCB, repeating the laser micromachining of PCB traces and the EID process; and
forming vias between at least some of the plurality of layers after the repeating of the laser micromachining of the PCB traces.
